(19) United States
(12) Patent Application Publication
(10) Pub. No.: US 2025/0125655 A1
(43) Pub. Date: Apr. 17, 2025

(54) ELECTRONIC DEVICE AND ELECTORNIC COMPONENT

(71) Applicant: GOPOD GROUP HOLDING LIMITED., Shenzhen (CN)

(72) Inventors: Zhuowen LIAO, Shenzhen (CN); Shipei LIN, Shenzhen (CN)

(21) Appl. No.: 18/429,044

(22) Filed: Jan. 31, 2024

Related U.S. Application Data
(63) Continuation of application No. PCT/CN2023/127982, filed on Oct. 30, 2023.

(30) Foreign Application Priority Data
Oct. 13, 2023 (CN) 202322778531.0

(51) Int. Cl. H02J 50/00; F21L 4/04; F21V 21/06; F21V 23/06; F21V 29/83; F21W 131/40

(52) U.S. Cl. CPC H02J 50/005; F21L 4/04; F21V 21/06; F21V 23/06; F21V 29/83; F21W 2131/40; H02J 2310/22

(57) ABSTRACT

An electronic device includes a housing, a wireless charging module and a lighting module. The housing has an accommodating cavity open at both ends and is provided with a partition. The partition separates the accommodating cavity to form a first accommodating groove and a second accommodating groove; the wireless charging module is arranged in the first accommodating groove; and the lighting module is arranged in the second accommodating groove; wherein, a heat dissipation hole is opened along the outer circumference of the housing, and connected with the first accommodating groove and/or the second accommodating groove.

### CROSS-REFERENCES TO RELATED APPLICATIONS

This disclosure claims priority to the Chinese patent application with application number 202322778531.0 and titled “An electronic device and electronic component” filed with the State Intellectual Property Office of China on Oct. 13, 2023, the entire content of which is incorporated into this disclosure by reference.

### TECHNICAL FIELD

The present disclosure relates to the technical field of electronic components, and in particular, to an electronic device and an electronic component.

### BACKGROUND OF THE PRESENT INVENTION

With the progress of society and the continuous improvement of people's living standards, camping by car has gradually become a popular tourism project. People can reduce the stress of life and get close to nature through camping.

But camping is usually in an outdoor environment. When night falls, because the visibility at night is very poor, a light source is needed. To solve this problem, a light is usually set up on an outdoor mobile power supply to provide lighting for the entire camping team.

However, the lighting lamp in the prior art only has a lighting function. When the user forgets to carry or loses the data cable, the smartphone cannot be charged and the battery life of the smartphone is affected.

### CONTENTS OF THE PRESENT INVENTION

In view of this, the purpose of the present disclosure is to overcome the deficiencies in the prior art and provide an electronic device to solve the problem that the lighting lamp in the prior art only has the lighting function. When the user forgets to carry or loses the data cable, the smartphone cannot be charged and the battery life of the smartphone is affected.

In order to solve the above technical problems, the present disclosure provides:
An electronic device, which includes:
A housing having an accommodating cavity open at both ends and provided with a partition, which separates the accommodating cavity to form a first accommodating groove and a second accommodating groove;
A wireless charging module, which is arranged in the first accommodating groove;
A lighting module, which is arranged in the second accommodating groove;
Wherein, a heat dissipation hole is opened along the outer circumference of the housing, and connected with the first accommodating groove and/or the second accommodating groove.

In addition, the electronic device according to the present disclosure may also have the following additional technical features:

In some embodiments of the present disclosure, the electronic device further includes a mask assembly, which includes a first mask and a second mask. The first mask is installed at the opening of the first accommodating groove. The second mask is installed at the opening of the second accommodating groove.

In some embodiments of the present disclosure, the second mask is made of transparent material and is integrally molded.

In some embodiments of the present disclosure, a plurality of heat dissipation holes are provided, which are spaced apart along the outer circumference of the housing.

In some embodiments of the present disclosure, the electronic device further includes a base, and the housing is movably disposed on the base.

In some embodiments of the present disclosure, the electronic device further includes a connecting piece that is hinged to the base and the housing respectively.

In some embodiments of the present disclosure, a first connection part is provided at an end of the base away from the housing.

In some embodiments of the present disclosure, the first connection part is provided with a first conductive part, which is electrically connected to the wireless charging module and the lighting module respectively.

In addition, the present disclosure also provides an electronic component, which includes an outdoor mobile power supply and the electronic device described in any of the above embodiments.

In some embodiments of the present disclosure, the electronic device is provided on the outdoor mobile power supply, which is provided with a second connection part at one end close to the electronic device, and the second connection part is provided with a second conductive part, which is electrically connected to the electronic device.

Compared with the existing technology, the beneficial effects of the present disclosure are:

The present disclosure proposes an electronic device, which includes a housing, a wireless charging module and a lighting module. The housing has an accommodating cavity open at both ends and is provided with a partition. The partition separates the accommodating cavity to form a first accommodating groove and a second accommodating groove. A lighting module is provided in the second accommodating groove to realize the lighting function of the electronic device. A wireless charging module is set in the first accommodating groove to realize the wireless charging function of the electronic device. When the user forgets to carry or loses the data cable, the smartphone can be charged through the wireless charging module of the electronic device, which improves the the battery life of the smart phone.

At the same time, the partition can also play a role in heat insulation, effectively reducing the interaction between the lighting module and the wireless charging module. By opening a heat dissipation hole connected to the first accommodating groove and/or the second accommodating groove along the outer circumference of the housing, it plays a role in heat dissipation, which is conducive to discharging the heat generated when the lighting module and the wireless charging module are working, and preventing excessive temperature. High temperature will cause damage to the lighting module and the wireless charging module. It effectively extends the service life of electronic device.

### DESCRIPTION OF THE DRAWINGS

In order to explain the technical solutions of the embodiments of the present disclosure more clearly, the drawings needed to be used in the embodiments will be briefly introduced below. It should be understood that the following drawings only show some embodiments of the present disclosure and therefore they should not be regarded as a limitation of the scope. For those of ordinary skill in the art, other relevant drawings can also be obtained based on these drawings without exerting creative efforts.

FIG. 1 shows a schematic three-dimensional view of an electronic device in some embodiments of the present disclosure;

FIG. 2 shows a second schematic three-dimensional view of an electronic device in some embodiments of the present disclosure;

FIG. 3 shows a three-dimensional view of FIG. 1 with the mask assembly omitted;

FIG. 4 shows a three-dimensional view of FIG. 2 with the mask assembly omitted;

FIG. 5 shows a third three-dimensional view of an electronic device in some embodiments of the present disclosure;

FIG. 6 shows a forth three-dimensional view of an electronic device in some embodiments of the present disclosure;

FIG. 7 shows a three-dimensional view of electronic components in some embodiments of the present disclosure;

FIG. 8 shows a schematic three-dimensional view of an outdoor mobile power supply in some embodiments of the present disclosure.

### DESCRIPTION OF MAIN COMPONENT SYMBOLS

100—electronic device; 110—housing; 111—accommodating cavity; 1111—first accommodating groove; 1112—second accommodating groove; 112—partition; 113—heat dissipation hole; 120—wireless charging module; 130—lighting module; 140—mask component; 141—first mask; 142—second mask; 150—base; 151—first connection part; 1511—first conductive part; 160—connecting piece; 1000—electronic component; 200—outdoor mobile power supply; 210—second connection part; 211—second conductive part.

### -DETAILED DESCRIPTION OF PREFERRED EMBODIMENTS

The present disclosure are described in detail below, examples of which are illustrated in the accompanying drawings, wherein the same or similar reference numerals throughout represent the same or similar elements or elements having the same or similar functions. The embodiments described below with reference to the drawings are exemplary and are only used to explain the present disclosure and are not to be construed as limitations of the present disclosure.

In the description of the present disclosure, it should be understood that the orientation or positional relationship indicated by “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, “clockwise”, “counterclockwise”, “axis” “radial direction”, “circumferential direction”, etc. is based on the orientation or positional relationship shown in the drawings, and is only for the convenience of describing the present disclosure and simplifying the description, rather than indicating or implying the device or device to which it is referred. Elements must have a specific orientation, be constructed and operate in a specific orientation and therefore are not to be construed as limitations of the disclosure.

In addition, the terms “first” and “second” are used for descriptive purposes only and cannot be understood as indicating or implying relative importance or implicitly indicating the quantity of indicated technical features. Therefore, features defined as “first” and “second” may explicitly or implicitly include one or more of these features. In the description of the present disclosure, “plurality” means two or more than two, unless otherwise expressly and specifically limited.

In this disclosure, unless otherwise clearly stated and limited, the terms “installation”, “connection”, “fixing” and other terms should be understood in a broad sense. For example, it can be a fixed connection or a detachable connection, or integration; it can be a mechanical connection or an electrical connection; it can be a direct connection or an indirect connection through an intermediate medium; it can be an internal connection between two elements or an interaction between two elements. For those of ordinary skill in the art, the specific meanings of the above terms in this disclosure can be understood according to specific circumstances.

In this disclosure, unless otherwise expressly stated and limited, a first feature being “on” or “below” a second feature may mean that the first and second features are in direct contact, or the first and second features may be in indirect contact through an intermediary. Furthermore, the first feature is “above”, “on top of” and “over” the second feature may mean that the first feature is directly above or diagonally above the second feature, or simply means that the first feature is higher in level than the second feature. The first feature is “below”, “under” and “beneath” the second feature may mean that the first feature is directly below or diagonally below the second feature, or simply means that the first feature has a lower horizontal height than the second feature.

### Embodiment 1

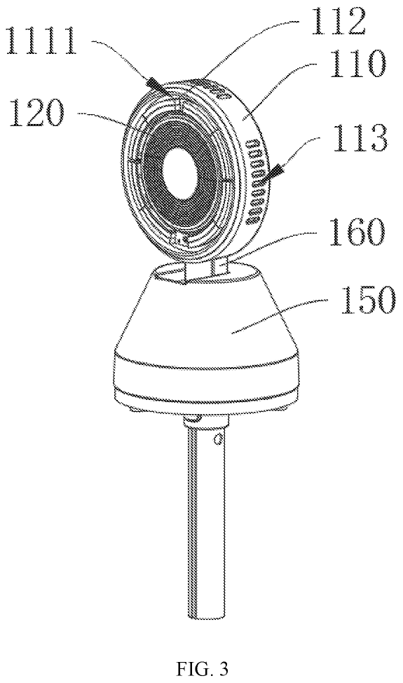

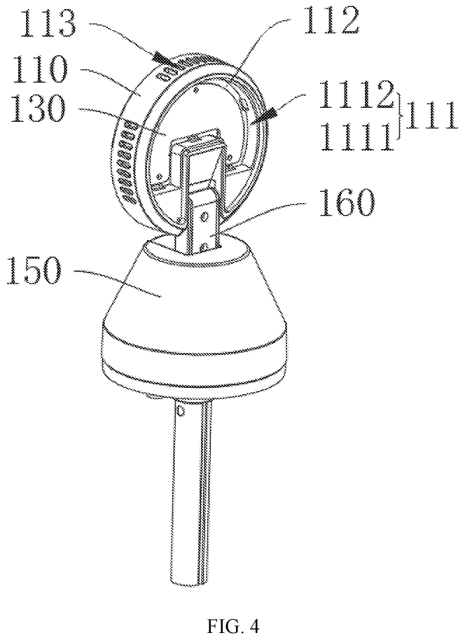

As shown in FIGS. 3 and 4, embodiment of the present disclosure provides an electronic device 100, which is mainly used in electronic components 1000. The electronic device 100 includes a housing 110, a wireless charging module 120, and a lighting module 130.

The housing 110 has an accommodating cavity 111 open at both ends and is provided with a partition 112. The partition 112 separates the accommodating cavity 111 to form a first accommodating groove 1111 and a second accommodating groove 1112. The wireless charging module 120 is disposed in the first accommodating groove 1111, and the lighting module 130 is disposed in the second accommodating groove 1112. A heat dissipation hole 113 is opened along the outer circumference of the housing 110, and the heat dissipation hole 113 is connected with the first accommodating groove 1111 and/or the second accommodating groove 1112.

The electronic device 100 is provided by embodiment of the present disclosure. The housing 110 has an accommodating cavity 111 open at both ends and is provided with a partition 112. The partition 112 separates the accommodating cavity 111 to form a first accommodating groove 1111 and a second accommodating groove 1112. By arranging the lighting module 130 in the second accommodating groove 1112, the lighting function of the electronic device 100 is realized, and by arranging the wireless charging module 120 in the first accommodating groove 1111, the wireless charging function of the electronic device 100 is realized. In this way, when the user forgets to carry or loses the data cable, the smartphone can be charged through the wireless charging module 120 of the electronic device 100, thereby improving the battery life of the smartphone. This method avoids the technical problem in the existing technology that the lighting lamp only has the lighting function. When the user forgets to carry or loses the data cable, the smartphone cannot be charged and the battery life of the smartphone is affected.

At the same time, the partition 112 can also play a role in heat insulation, effectively reducing the mutual influence caused by the heat generated by the lighting module 130 and the wireless charging module 120. By opening a heat dissipation hole 113 connected with the first accommodating groove 1111 and/or the second accommodating groove 1112 along the outer circumference of the housing 110, the heat dissipation effect is played, which is beneficial to the heat generated when the lighting module 130 and the wireless charging module 120 are working. The heat is discharged to prevent the lighting module 130 and the wireless charging module 120 from being damaged due to excessive temperature, effectively extending the service life of the electronic device 100.

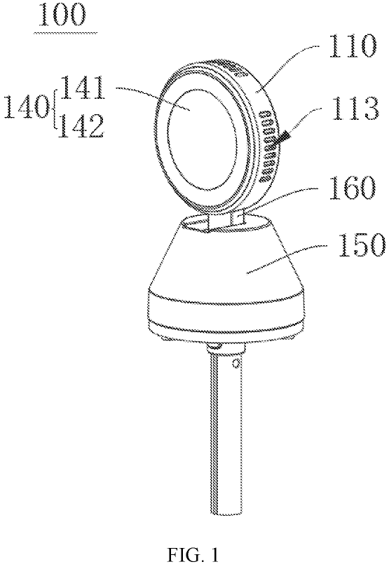

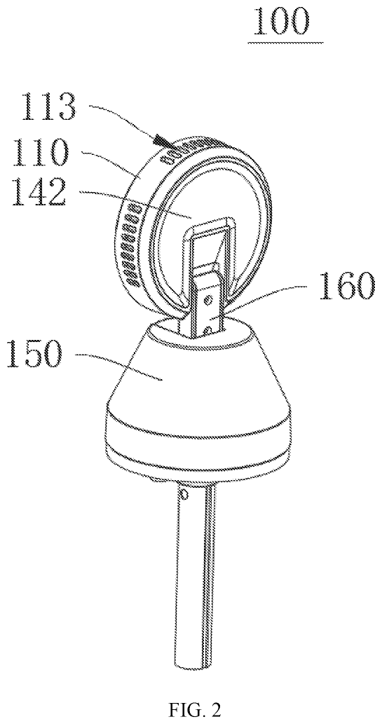

As shown in FIGS. 1 and 2, in one embodiment of the present disclosure, optionally, the electronic device 100 further includes a mask assembly 140, which includes a first mask 141 and a second mask 142. The first mask 141 is installed at the opening of the first accommodating groove 1111, and the second mask 142 is installed at the opening of the second accommodating groove 1112.

In this embodiment, by disposing the first mask 141 at the opening of the first accommodating groove 1111, on the one hand, it can protect the wireless charging module 120 in the first accommodating groove 1111, and improve the performance of the electronic device 100. On the other hand, it is aesthetically pleasing and can also serve as a place to facilitate placing a smartphone on the first mask 141 for wireless charging.

By disposing the second mask 142 at the opening of the second accommodating groove 1112, the lighting module 130 in the second accommodating groove 1112 is protected, and the aesthetics of the electronic device 100 is improved.

Among them, the first mask 141 and the second mask 142 are detachably connected to the housing 110 to facilitate the installation, disassembly, maintenance and replacement of the wireless charging module 120 and the lighting module 130.

In the above embodiment of the present disclosure, optionally, the second mask 142 is made of a transparent material and is integrally molded.

In this embodiment, the second mask 142 is made of a transparent material and is integrally molded, so that the light emitted by the lighting module 130 can pass through the second mask 142 and shine into the external environment, thereby realizing its lighting function.

For example, the material of the second mask 142 may be transparent PC (Polycarbonate), PS (Polystyrene), PMMA (Polymethyl methacrylate), and other materials.

In the above embodiment of the present disclosure, optionally, an atomized layer or light-transmitting paint is provided on the side of the second mask 142 away from the second accommodating groove 1112.

In this embodiment, by providing an atomized layer or spraying light-transmitting paint on the surface of the second cover 142 on the side away from the second accommodating groove 1112, the atomized layer or light-transmitting paint can make the light emitted by the lighting module 130 uniform and achieve the fogging effect of light. At the same time, it can also prevent the user from directly observing the internal structure of the second accommodating groove 1112 from the outside with the naked eye, thereby improving the aesthetics.

Optionally, the atomization layer may be a frosted layer or a textured layer, that is, the surface of the second mask 142 may be subjected to a frosting process or a textured process, so that the light emitted by the lighting module 130 has a fogging effect.

As shown in FIGS. 1 and 2, in one embodiment of the present disclosure, optionally, a plurality of heat dissipation holes 113 are provided, which are spaced apart along the outer circumference of the housing 110.

In this embodiment, by setting the number of heat dissipation holes 113 to multiple and arranging the plurality of heat dissipation holes 113 at intervals along the outer circumference of the housing 110, the heat dissipation effect can be further improved, which further facilitates the heat discharge when the lighting module 130 and the wireless charging module 120 are working. This prevents the lighting module 130 and the wireless charging module 120 from being damaged due to excessive temperature and effectively extends the service life of the electronic device 100.

As shown in FIGS. 1 and 2, in any of the above embodiments of the present disclosure, optionally, the electronic device 100 further includes a base 150, and the housing 110 is movably disposed on the base 150.

In this embodiment, the housing 110 is movably disposed on the base 150 to adjust the angle between the housing 110 and the base 150, thereby facilitating outdoor lighting or wireless charging of the smartphone.

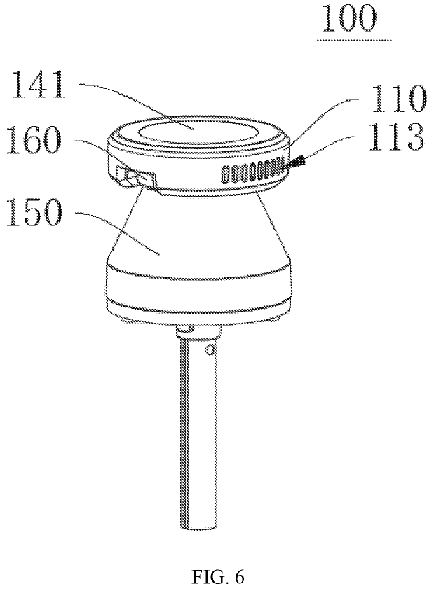

As shown in FIGS. 1, 2 and 6, in the above embodiments of the present disclosure, optionally, the electronic device 100 further includes a connecting piece 160, which is hinged to the base 150 and the housing 110.

In this embodiment, the connecting piece 160 is hinged to the base 150 and the housing 110 respectively, so that the housing 110 can rotate relative to the base 150 to adjust the angle between the housing 110 and the base 150, thereby adjusting the lighting direction of the lighting module 130. At the same time, the housing 110 is adjusted to any angle with the base 150. At this time, the smart phone is placed on the electronic device 100 to achieve magnetic wireless charging.

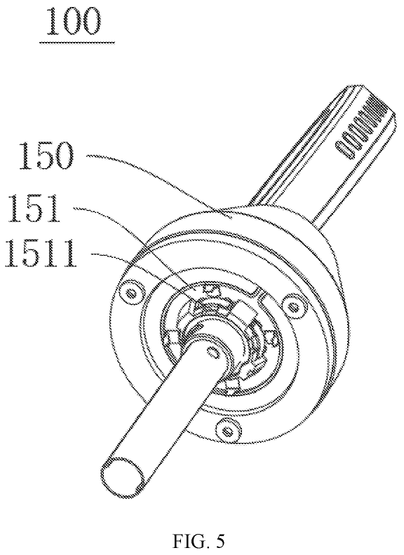

As shown in FIG. 5, in the above-mentioned embodiment of the present disclosure, optionally, a first connection portion 151 is provided at an end of the base 150 away from the housing 110.

In this embodiment, the first connection part 151 is provided at an end of the base 150 away from the housing 110 to connect to the outdoor mobile power supply 200 through the first connection part 151.

As shown in FIG. 5, in any of the above embodiments of the present disclosure, optionally, the first connection part 151 is provided with a first conductive part 1511, which is electrically connected to the wireless charging module 120 and the lighting module 130 respectively.

In this embodiment, by disposing the first conductive part 1511 on the first connection part 151, the outdoor mobile power supply 200 is electrically connected through the first conductive part 1511. At the same time, the first conductive part 1511 is electrically connected to the wireless charging module 120 and the lighting module 130 respectively, thereby realizing the power supply function for the wireless charging module 120 and the lighting module 130.

For example, the first conductive part 1511 may be a metal conductive sheet.

### Embodiment 2

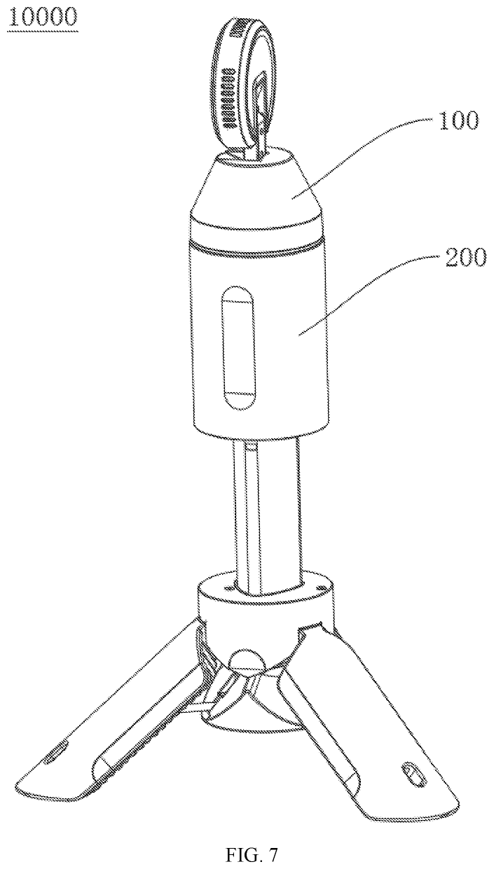

As shown in FIG. 7, embodiment 2 of the present disclosure also provides an electronic component 1000, which includes an outdoor mobile power supply 200 and the electronic device 100 described in any of the above embodiments 1.

The electronic component 1000 has the electronic device 100 described in embodiment 1, and therefore has all the beneficial effects of the electronic device 100 described in embodiment 1, which will not be described again here.

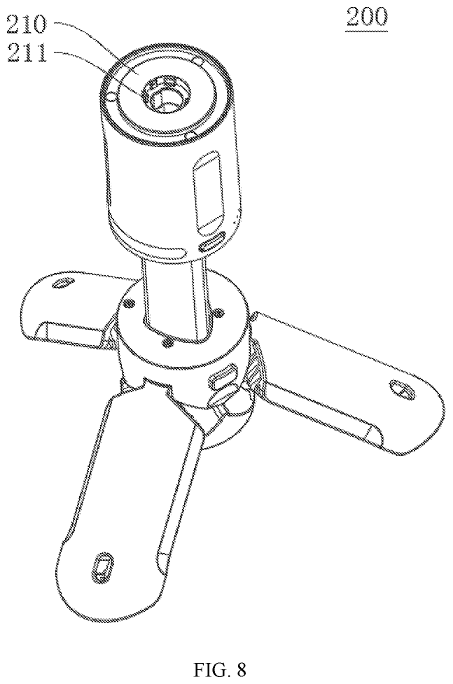

As shown in FIG. 8, in the above embodiment of the present disclosure, optionally, the electronic device 100 is provided on the outdoor mobile power supply 200, which is provided with a second connection part 210 at one end close to the electronic device 100. The second connection part 210 is provided with a second conductive part 211, which is electrically connected to the electronic device 100.

In this embodiment, the second connection part 210 is provided at one end of the outdoor mobile power supply 200 close to the electronic device 100, so that the electronic device 100 and the outdoor mobile power supply 200 are connected through the connection between the first connection part 151 and the second connection part 210.

By disposing the second conductive part 211 on the second connection part 210, the electrical connection between the electronic device 100 and the outdoor mobile power supply 200 is achieved through the contact between the first conductive part 1511 and the second conductive part 211, thereby achieving the power supply function for the wireless charging module 120 and lighting module 130.

For example, the second conductive part 211 may be a metal conductive sheet.

To sum up, the present disclosure proposes an electronic device 100, which includes a housing 110, a wireless charging module 120 and a lighting module 130. The housing 110 has an accommodating cavity 111 open at both ends and is provided with a partition 112. The partition 112 separates the accommodating cavity 111 to form a first accommodating groove 1111 and a second accommodating groove 1112. By disposing the lighting module 130 in the second accommodating groove 1112, the lighting function of the electronic device 100 is realized. By setting the wireless charging module 120 in the first accommodating groove 1111, the wireless charging function of the electronic device 100 is realized. So that when the user forgets to carry or loses the data cable, the smartphone can be charged through the wireless charging module 120 of the electronic device 100, thereby improving the battery life of the smartphone.

At the same time, the partition 112 can also play a role in heat insulation, effectively reducing the mutual influence caused by the heat generated by the lighting module 130 and the wireless charging module 120. By opening a heat dissipation hole 113 connected with the first accommodating groove 1111 and/or the second accommodating groove 1112 along the outer circumference of the housing 110, the heat dissipation effect is played, which is beneficial to the heat generated when the lighting module 130 and the wireless charging module 120 are working. The heat is discharged to prevent the lighting module 130 and the wireless charging module 120 from being damaged due to excessive temperature, which effectively extends the service life of the electronic device 100.

In the description of this specification, reference to a description of the terms “one embodiment,” “some embodiments,” “an example,” “a specific example,” or “some examples” or the like means that a particular feature, structure, material, or characteristic described in connection with the embodiment or example is included in at least one embodiment or example of the present disclosure. In this specification, the schematic expressions of the above terms are not necessarily directed to the same embodiment or example. Furthermore, the specific features, structures, materials or characteristics described may be combined in any suitable manner in any one or more embodiments or examples. Furthermore, those skilled in the art may combine different embodiments or examples and features of different embodiments or examples described in this specification unless they are inconsistent with each other.

Although the present disclosure has been shown and described above, it can be understood that the above-mentioned embodiments are illustrative and should not be construed as limitations of the present disclosure. Those of ordinary skill in the art can make various modifications within the scope of the present disclosure. The above-described embodiments are subject to changes, modifications, substitutions and variations.

### INDUSTRIAL APPLICABILITY

The present disclosure provides an electronic device and an electronic component. The electronic device includes a housing, a wireless charging module and a lighting module. The housing has an accommodating cavity open at both ends and is provided with a partition. The partition separates the accommodating cavity to form a first accommodating groove and a second accommodating groove. A lighting module is provided in the second accommodating groove to realize the lighting function of the electronic device. By setting a wireless charging module in the first accommodating groove to realize the wireless charging function of the electronic device, so that when the user forgets to carry or loses the data cable, the smartphone can be charged through the wireless charging module of the electronic device, which improves the battery life of the smartphone. In addition, the partition can also play a role in heat insulation, effectively reducing the interaction between the lighting module and the wireless charging module. By opening a heat dissipation hole connected to the first accommodating groove and/or the second accommodating groove along the outer circumference of the housing, it plays a role in heat dissipation, which is conducive to discharging the heat generated when the lighting module and the wireless charging module are working, and preventing excessive temperature. High temperature will cause damage to the lighting module and wireless charging module. This effectively extends the service life of electronic equipment.

Furthermore, it will be appreciated that the electronic devices and electronic components provided by the present disclosure are reproducible and can be used in a variety of industrial applications.

1. An electronic device, characterized by comprising:
a housing having an accommodating cavity open at both ends and provided with a partition, which separates the accommodating cavity to form a first accommodating groove and a second accommodating groove;
a wireless charging module, which is arranged in the first accommodating groove;
a lighting module, which is arranged in the second accommodating groove;
wherein, a heat dissipation hole is opened along the outer circumference of the housing, and connected with the first accommodating groove and/or the second accommodating groove.

2. The electronic device according to claim 1, characterized in that the electronic device further includes a mask assembly, which includes a first mask and a second mask;
the first mask is installed at the opening of the first accommodating groove; the second mask is installed at the opening of the second accommodating groove.

3. The electronic device according to claim 2, characterized in that the second mask is made of transparent material and is integrally molded.

4. The electronic device according to claim 1, characterized in that there are a plurality of heat dissipation holes, which are spaced apart along the outer circumferential direction of the housing.

5. The electronic device according to claim 1, characterized in that the electronic device further includes a base, and the housing is movably disposed on the base.

6. The electronic device according to claim 5, characterized in that the electronic device further comprises a connecting piece, which is hinged to the base and the housing respectively.

7. The electronic device according to claim 5, characterized in that a first connection part is provided at an end of the base away from the housing.

8. The electronic device according to claim 7, characterized in that the first connection part is provided with a first conductive part, which is electrically connected to the wireless charging module and the lighting module respectively.

9. An electronic component, characterized by comprising an outdoor mobile power supply and the electronic device according to claim 1.

10. The electronic component according to claim 9, characterized in that the electronic device is provided on the outdoor mobile power supply, and a second connection part is provided on one end of the outdoor mobile power supply close to the electronic device, and the second connection part is provided with a second conductive part, which is electrically connected to the electronic device.
